(19) United States
(12) Patent Application Publication
(10) Pub. No.: US 2003/0029837 A1
(43) Pub. Date: Feb. 13, 2003

(54) Dielectric etch plasma chamber utilizing a magnetic filter to optimize plasma characteristics

(75) Inventor: John R. Trow, San Jose, CA (US)

Correspondence Address: APPLIED MATERIALS, INC., 2881 SCOTT BLVD. M/S 2061, SANTA CLARA, CA, 95050, US

(73) Assignee: Applied Materials, Inc.

(21) Appl. No.: 09/927,304

(22) Filed: Aug. 10, 2001

(51) Int. Cl. H01L 21/3065

(52) U.S. Cl. 216/67; 216/79; 216/80; 438/723; 438/732

(57) ABSTRACT

A method and a system for etching a substrate are disclosed. The substrate is disposed in a process chamber. A flow of precursor gas is introduced into the process chamber. An ionic plasma is then formed from the precursor gas in a plasma volume within the process chamber. A magnetic field is generated in the process chamber using magnetic sources disposed external to the plasma volume. The magnetic field divides the ionic plasma into a two regions, plasma within one region having a higher electron temperature than plasma within the other region. The low-electron temperature region is confined substantially above the substrate. Radicals are formed in this region for etching the substrate.

### BACKGROUND OF THE INVENTION

The increasing complexity and miniaturization of integrated circuit technology is driving the semiconductor industry. The demand for improved resolution requires imaging features with increasingly higher aspect ratios and smaller linewidth variation over steep substrate topography. The semiconductor industry is increasingly employing medium and high density reactors such as inductively coupled plasma (ICP) systems as well as magnetron and helicon plasmas. These technologies offer the ability for higher rates and control of the ion energy for selectivity.

In high density reactive ion etching (RIE) systems its has been found that electrons diffuse nearly isotropically from the plasma source towards the wafer when the bias voltage is near its maximum (Keller et al, Jpn. J. Appl. Phys. Vol. 38 (1999) pp. 4280-4282). One approach for decreasing the bias voltage in RF systems involves applying a magnetic field to the plasma. The magnetic field confines the electrons to the region near the surface of the wafer and increases the ion flux density and ion current. In this way, the voltage and ion energy requirements are reduced. In a nonmagnetic RIE process for etching silicon dioxide an RF energy at 13.56 MHz is applied to a system of 10-15 liters volume, 50 millitorr pressure and an anode area to wafer-support cathode area ratio of approximately (8-10) to 1, and develop wafer (cathode) sheath voltage of approximately 800 volts. The application of a magnetic field of 60 gauss allows a decrease of 25-30 percent of the bias voltage while allowing an increase in the etch rate by approximately 50 percent.

The intent for using magnetic fields has previously been for control of the electron energy for enhancing the production of negative ion species, such as H⁻ ions, which are only weakly bound by about 0.75 eV. It is, however, desirable to provide a system not only for controlling the energy and flux of the plasma electrons and ions but also to enhance the chemical radical formation at the surface of the wafer.

### SUMMARY OF THE INVENTION

Thus, embodiments of the present invention provide a method for etching a substrate. The substrate is disposed in a process chamber, which is provided with a flow of precursor gas. An ionic plasma is formed from the precursor gas in a plasma volume within the process chamber. In one embodiment, the ionic plasma is a negative-ion plasma. A magnetic field is generated within the process chamber using magnetic sources disposed external to the plasma volume such that the magnetic field divides the ionic plasma into two regions. Plasma within the first region has a higher electron temperature than plasma within the second region, which is confined substantially above the substrate. Radicals are formed from the plasma within the second region to etch the substrate.

In one embodiment the substrate comprises a silicon oxide layer. The ionic plasma may be formed by ionizing the precursor gas using a radio-frequency source. In a particular embodiment, the precursor gas comprises freon molecules and may comprise a mixture of argon and freon. The radicals formed in the second region may thus be formed by dissociating C₄F₈ molecules into radical species that include CF₂ or include CF₃. The magnetic sources may be provided by permanent magnets or may be provided by electromagnets in different embodiments.

The methods of the present invention may be performed with a substrate processing system. Such a system may include a process chamber, a plasma generation system, a substrate holder, a gas delivery system, and a system controller. The magnetic sources are disposed outside the process chamber to provide a magnetic field for dividing the ionic plasma into two regions, including a low-electron-temperature region confined substantially above the substrate for forming radicals to etch the substrate.

A further understanding of the nature and advantages of the present invention may be realized by reference to the remaining portions of the specification and the drawings.

### BRIEF DESCRIPTION OF THE DRAWINGS

FIG. 1 shows the electron interaction cross sections for C₃F₈ provided by NIST;

FIG. 2 is a cross-sectional view of the plasma etch reactor of the invention showing the disposition of the plasma source, the disposition of the substrate and various elements and the shapes of the magnetic field lines within the chamber;

FIG. 3 is a schematic process for formation of radicals on the surface of the dielectric substrate;

FIG. 4 is a flow chart showing the method steps for etching a substrate according to the present invention;

FIG. 5A illustrates one embodiment of a plasma etching system according to the present inevntion;

FIG. 5B is a simplified, partial cross-sectional view of processing chamber showing additional details of gas ring inlet;

FIG. 5C is an illustration of a portion of an exemplary system user interface used in conjunction with the exemplary plasma processing chamber of FIG. 5A; and

FIG. 5D is an illustrative block diagram of the hierarchical control structure of computer program controlling the plasma processing sequence according to the present invention.

### DESCRIPTION OF THE SPECIFIC EMBODIMENTS

Overview

Magnetic-filter embodiments of the invention provide a method and apparatus for enhancing dielectric etch by increasing the yield of chemical radical formation. This is achieved by disposing a dielectric substrate in a plasma chamber. An ionic plasma, such as a negative-ion plasma, is then formed in the plasma chamber from a precursor gas. In addition to ionic species, the plasma comprises electrons. In one embodiment, the precursor gas comprises C₄F₈, and mad additionally comprise argon. A magnetic field is then generated in the plasma chamber using magnetic sources disposed external to the plasma volume where the plasma is formed. The magnetic field is configured in such a manner as to divide the ionic plasma into two regions. The plasma in the first region has a higher electron temperature and the plasma in the second region has a lower electron temperature. In this way, the cooler plasma of the second region is confined above the substrate intended for processing. Subsequently, radicals are formed from the plasma in the second region above the substrate for etching the dielectric substrate, which in one embodiment is silicon oxide.

In one embodiment, the ionic plasma is created using a radio-frequency (RF) source or microwave power source. The frequency for generating RF energy may be within the range 100 kHz to 100 MHz. The RF energy may be controlled by a tunable antenna. In one embodiment, the tuning process is controlled by a variable capacitance electrically connected between one end of the antenna and RF ground.

In one embodiment, the magnetic field in the plasma chamber is generated using a series of permanent magnets or using an electromagnetic arrangement, such as may be provided with a set of DC coils disposed around the plasma chamber, to apply a controlled static magnetic field. In addition, magnetic sources may be mounted around the plasma chamber for applying a multipolar cusp field to the chamber in the vicinity of the substrate. This acts to confine the high-energy plasma away from the substrate region while substantially eliminating the magnetic field across the substrate. The effect of this magnetic field is to act as a magnetic filter that divides the plasma into the high-electron-temperature and low-electron-temperature regions as described above. Radicals are formed in the second (low-electron-temperature) region via electron attachment followed by dissociative processes.

Etchant Radical Formation Mechanism

Dissociative electron-molecule collisions play a key role in a variety of plasma processes such as plasma-enhanced chemical vapor deposition and low-temperature plasma etching. Electron-molecule dissociation cross sections are relatively difficult to measure because of well-known problems with the detection of neutral fragments. Indeed, the number of systems for which experimental measurements have been made is quite small. In cases where electron-impact dissociation produces electronically excited fragments decaying radiatively, studies use the optical excitation function technique. Emissions have been measured over a wide spectral range. Several molecules relevant to plasma processing have been studied, providing dissociation cross sections for CF₄, SF₆, NF₃, BCl₃ (A. Blanks, A. E. Tabor, and K. Becker, J. Chem. Phys. 86:4871 (1987) and P. G. Gilbert, R. B. Siegel, and K. Becker, Phys. Rev. A 41:5594 (1990)) and several freons (L. G. Christophorou and J. K. Olhoff, Electron Interactions with C₃F₈, J. Phys. Chem. Ref Data, 27, No. 5, pp. 889-913 (1998)). “Freon” refers generally to fluorocarbon compounds, including C₃F₈ and C₄F₈. Data on electron-molecule collisional processes provides the identities of key chemical species and the dominant kinetic pathways that determine the concentrations and reactivities of these key species. In some cases, numerous dissociative channels leading to various products are possible in electron-molecule collision, especially when the molecule presents a large number of atoms, such as in freon molecules.

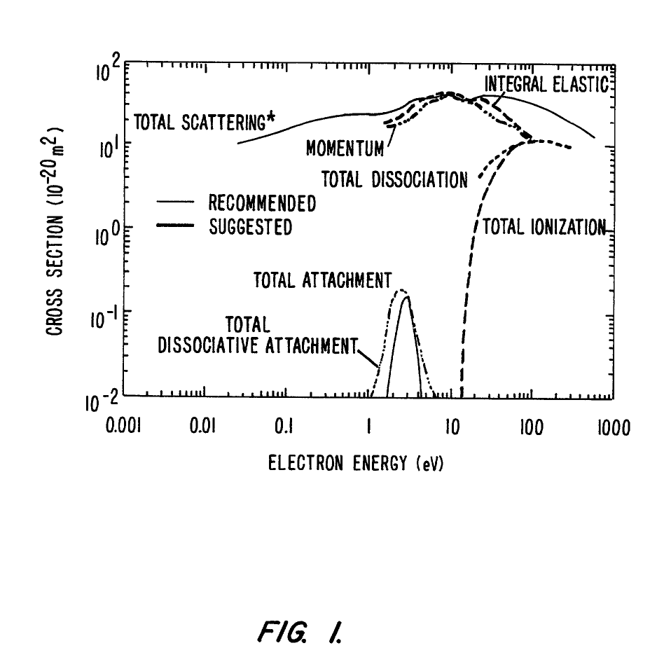

The advantage of controlling the energy of the electrons by using the magnetic filter discussed previously is that it is then possible to enhance chemical radical formation without over-dissociating the precursor gas. Radical species formed above the substrate may then be used to etch the substrate. In one embodiment, the precursor gas is a mixture of a freon and an inert gas such as argon. In a particular embodiment, the freon is C₄F₈. According to embodiments of the present invention, it is possible not only to control the formation of ions but also to control the fluorine chemistry used for oxide etch. Indeed, such embodiments permit an increase in the yield of radical formation of CF₃ and CF₂ species while limiting the formation of other radical or ionic species. In addition to CF₃ and CF₂ radicals, formation of other radicals in the electron-C₄F₈ collision is possible. It has been shown, for perfluoropropane C₃F₈, that dissociative processes occur within the electron energy interval of 1 eV to 300 eV (see the discussion related to FIG. 1 below). Complete cross-section measurements for C₄F₈ appear to be unavailable. However, relevant reaction information is provided by C₃F₈ cross-section data. Indeed, it is evident from such cross-section results that higher radical yield is achieved by maintaining a low collisional energy between the electrons in the plasma and the precursor gas.

FIG. 1 shows the electron interaction cross sections for the C₃F₈ molecule. The electron energy represents the energy of the incident electron in units of electron volts. The curve labeled “Total Scattering” represents the total electron scattering cross section in units of 10⁻²⁰ m². The curve labeled “Elastic Integral” represents the integral elastic electron scattering cross section in units of 10⁻²⁰ m². The curve labeled “Momentum Transfer” represents the elastic momentum transfer cross section in units of 10⁻²⁰ m². The curve labeled “Total Ionization” represents the total electron-impact ionization cross section in units of 10⁻²⁰ m². The curve labeled “Total Dissociation” represents the total electron-impact dissociation cross section in units of 10⁻²⁰ m². The curve labeled “Total Attachment” represents the total electron-attachment cross section in units of 10⁻²⁰ m². In particular, it represents the sum of cross sections for attachment processes producing parent negative ions and fragment negative ions. The curve labeled “Dissociative Attachment” represents the dissociative electron-attachment cross section in units of 10⁻²⁰ m². It represents the cross section only for processes producing fragment negative ions.

The data presented on FIG. 1 offer insight as to which process is predominant at certain electron collision energies. In particular, it may be seen that the dissociative attachment, that is a dissociation channel with one of the products of the collision being ionic, appears between approximately 1 eV and 8 eV. However, the cross section of the dissociative attachment channel is two order of magnitude lower than the total scattering cross section, meaning that this process is negligible in comparison with other processes such as elastic and momentum transfer collisions. In comparison, the total dissociation cross-section leading to radical species (neutral molecules) becomes important at around 10 eV and stays at a value of approximately 10×10⁻²⁰ m² up to an electron energy of about 300 eV. In the electron energy range 20-100 eV the total dissociation and the total ionization channels have approximately equal cross section values meaning that in this interval of energy the probability of producing ions or radicals is about the same. Therefore, a compromise may be negotiated in terms of the electron energy to dissociate the parent molecule C₃F₈ to produce radicals without over-dissociating the freon molecule.

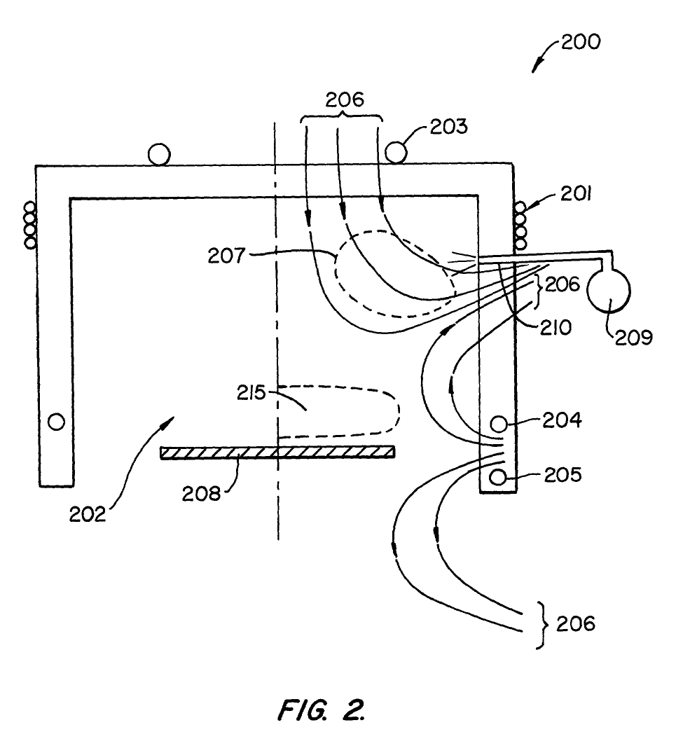

The mechanism of the invention may be better understood with reference to FIG. 2, in which a schematic cross-sectional view of a plasma etch reactor 200 that may be used with the invention is shown. A plasma generator 201, such as an RF source, is mounted on top of the plasma processing chamber 202. A gas source 209 provides a plasma process gas through inlet 210. An exhaust pump (not shown in FIG. 2) withdraws process gases and reaction by-products at a rate sufficient to produce an appropriate pressure within processing chamber 202.

A series of DC coils 203, 204, 205 are disposed around plasma chamber 202 in order to create the magnetic field represented by magnetic field lines 206. The magnetic field lines 206 confine high-temperature-electron plasma 207 away from the substrate 208. Indeed, due to the Lorentz relationship F=q (v×B), which provides the force F on particles of charge q traveling at velocity v in field B, the high-energy electrons in the plasma are bent back or repelled by the magnetic field and are not able to penetrate to the substrate processing region 215. Therefore, the presence of high-energy electrons is substantially reduced in the processing region 215. The processing region 215 is instead populated with lower-temperature electrons to provide a better scheme for chemical radical production. Indeed, as mentioned previously, dissociative attachment processes occur, preferably, at low electron collision energy. The approach using a magnetic filter disposed outside the plasma offers the advantage of enhancing the etch process by increasing the yield of radical species formation.

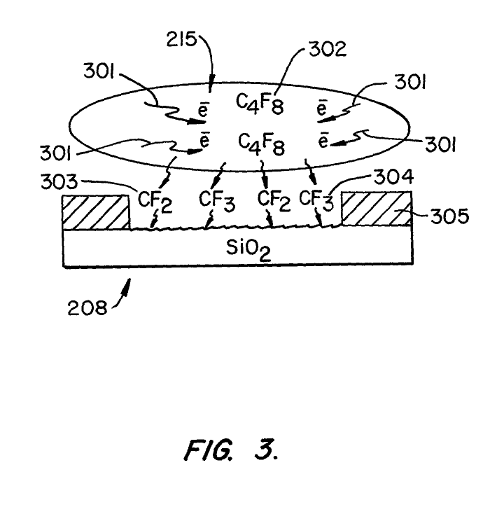

Referring to FIG. 3, a process is shown schematically for formation of radicals on the surface of the dielectric substrate when etching of silicon oxide layers with fluorine-based etchant molecules is desired. Low-energy electrons 301 present in the low-temperature plasma 215 collide with freon C₄F₈ molecules 302, leading to formation of radical species 303 and 304. In one embodiment, these radical species are respectively CF₂ and CF₃ molecules. Radicals 303 and 304 etch the dielectric substrate 208, which may comprise a layer of silicon oxide. To produce a structure for etching, photoresist mask 305 is used to protect those portions of the silicon oxide layer not intended for etching.

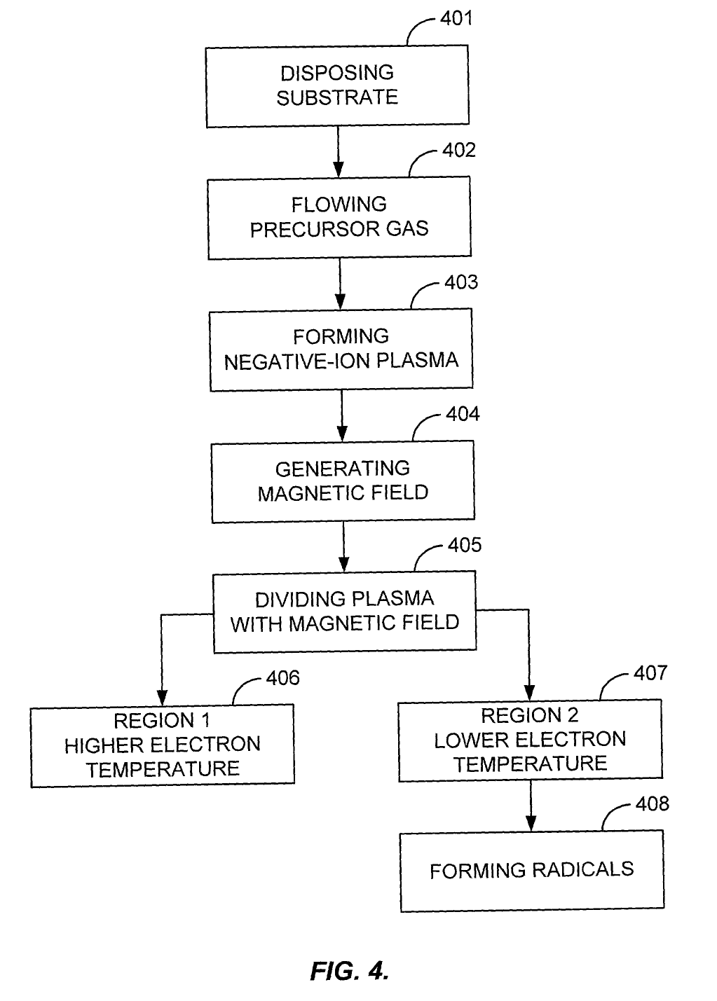

FIG. 4 is an exemplary flow chart showing the method steps for etching a substrate according to the present invention. The illustrated method begins at block 401 by disposing the substrate in a process chamber. At block 402 a flow of process precursor gas is provided into the chamber. At block 403 a negative-ion plasma is formed from the precursor gas in a plasma volume within the process chamber. At block 404 a magnetic field is generated in the process chamber using magnetic sources disposed external to the plasma volume. At block 405 the negative-ion plasma is divided with the magnetic field into a first region 406 and a second region 407, plasma in the first region 406 having a higher electron temperature than plasma within the second region 407. The second region 407 is confined substantially above the substrate. Radicals are formed at block 408 from the plasma region 407 for etching the substrate.

Exemplary Substrate Processing System

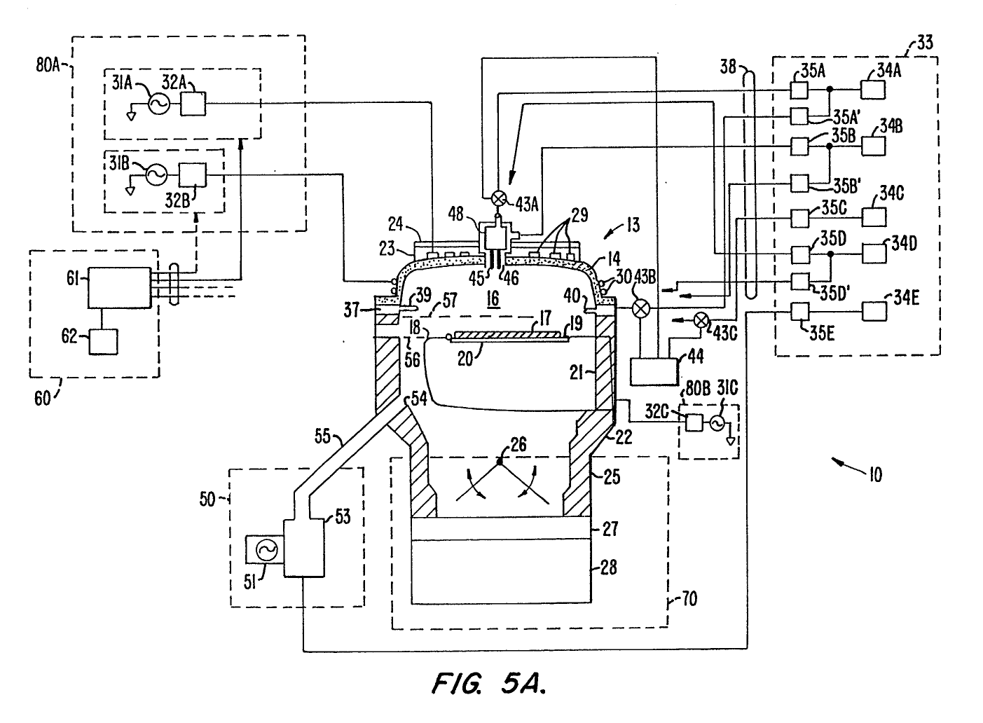

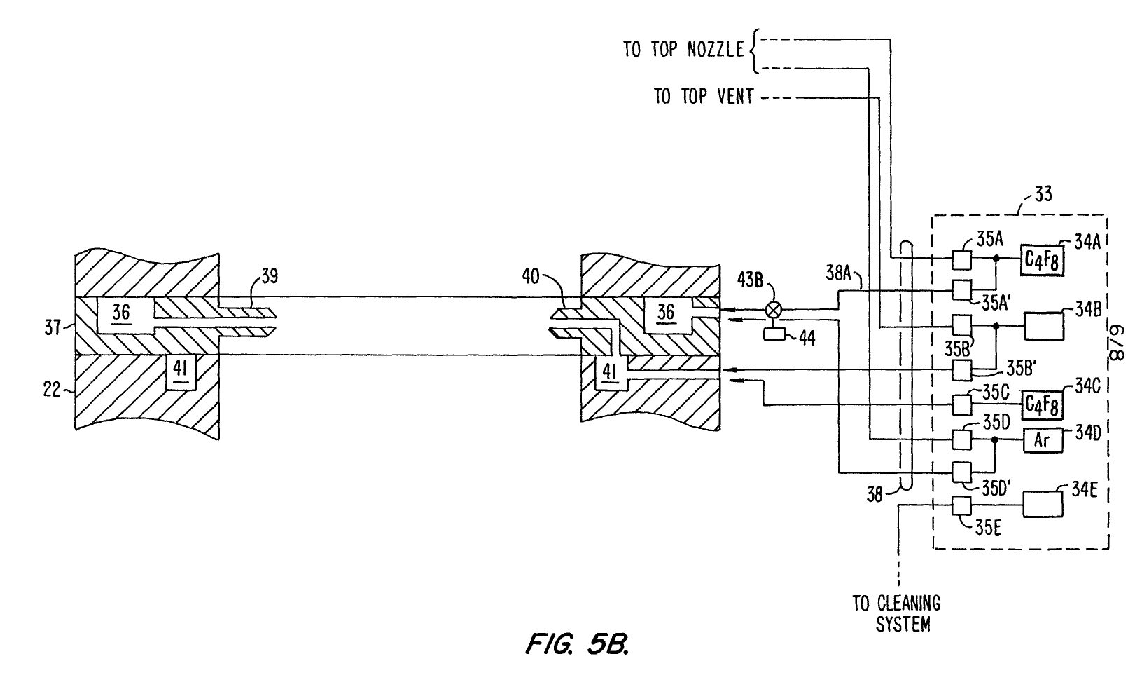

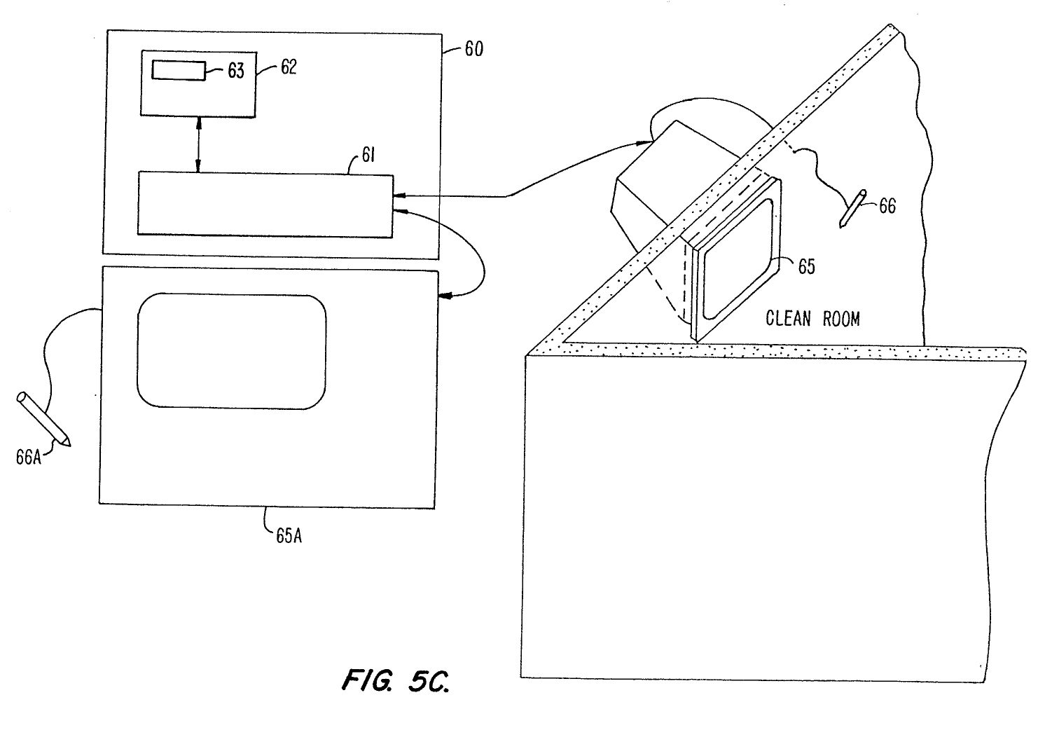

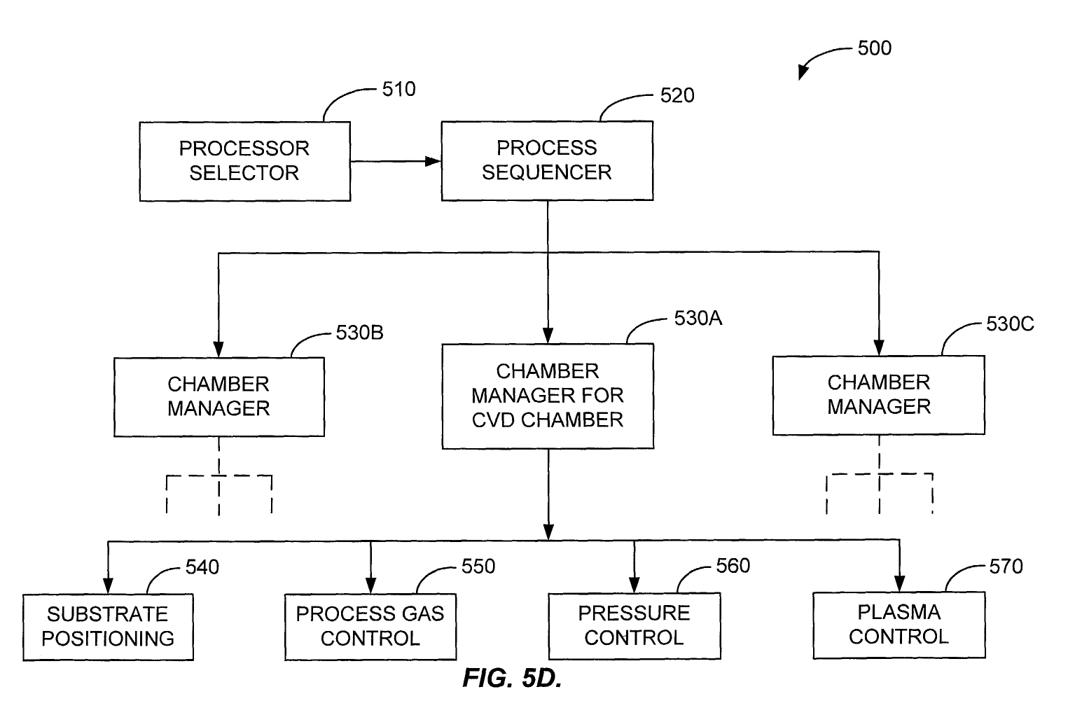

The following is a description of a plasma processing chamber that may be used for practicing embodiments of the present invention. FIG. 5A illustrates one embodiment of a plasma etching system 10 in which a dielectric according to the present invention can be etched. System 10 includes a chamber 13, a vacuum system 70, a source plasma system 80A, a bias plasma system 80B, a gas delivery system 33, and a remote plasma cleaning system 50.

The upper portion of chamber 13 includes a dome 14, which is made of a ceramic dielectric material, such as aluminum oxide or aluminum nitride. Dome 14 defines an upper boundary of a plasma processing region 16. Plasma processing region 16 is bounded on the bottom by the upper surface of a substrate 17 and a substrate support member 18.

A heater plate 23 and a cold plate 24 surmount, and are thermally coupled to, dome 14. Heater plate 23 and cold plate 24 allow control of the dome temperature to within about ±10° C. over a range of about 100° C. to 200° C. This allows optimizing the dome temperature for the various processes. For example, it may be desirable to maintain the dome at a higher temperature for etching (or cleaning) processes than would be desirable for deposition processes.

The lower portion of chamber 13 includes a body member 22, which joins the chamber to the vacuum system. A base portion 21 of substrate support member 18 is mounted on, and forms a continuous inner surface with, body member 22. Substrates are transferred into and out of chamber 13 by a robot blade (not shown) through an insertion/removal opening (not shown) in the side of chamber 13. Lift pins (not shown) are raised and then lowered under the control of a motor (also not shown) to move the substrate from the robot blade at an upper loading position 57 to a lower processing position 56 in which the substrate is placed on a substrate receiving portion 19 of substrate support member 18. Substrate receiving portion 19 includes an electrostatic chuck 20 that secures the substrate to substrate support member 18 during substrate processing. In a preferred embodiment, substrate support member 18 is made from an aluminum oxide or aluminum ceramic material.

Vacuum system 70 includes throttle body 25, which houses twin-blade throttle valve 26 and is attached to gate valve 27 and turbo-molecular pump 28. It should be noted that throttle body 25 offers minimum obstruction to gas flow, and allows symmetric pumping. Gate valve 27 can isolate pump 28 from throttle body 25, and can also control chamber pressure by restricting the exhaust flow capacity when throttle valve 26 is fully open. The arrangement of the throttle valve, gate valve, and turbo-molecular pump allow accurate and stable control of chamber pressures from between about 1 millitorr to about 2 torr.

The source plasma system 80A includes a top coil 29 and side coil 30, mounted on dome 14. A symmetrical ground shield (not shown) reduces electrical coupling between the coils. Top coil 29 is powered by top source RF (SRF) generator 31A, whereas side coil 30 is powered by side SRF generator 31B, allowing independent power levels and frequencies of operation for each coil. This dual coil system allows control of the radial ion density in chamber 13, thereby improving plasma uniformity. Side coil 30 and top coil 29 are typically inductively driven, which does not require a complimentary electrode. In a specific embodiment, the top source RF generator 31A provides up to 2,500 watts of RF power at nominally 2 MHz and the side source RF generator 31B provides up to 5,000 watts of RF power at nominally 2 MHz. The operating frequencies of the top and side RF generators may be offset from the nominal operating frequency (e.g. to 1.7-1.9 MHz and 1.9-2.1 MHz, respectively) to improve plasma-generation efficiency.

A bias plasma system 80B includes a bias RF (“BRF”) generator 31C and a bias matching network 32C. The bias plasma system 80B capacitively couples substrate portion 17 to body member 22, which act as complimentary electrodes. The bias plasma system 80B serves to enhance the transport of plasma species (e.g., ions) created by the source plasma system 80A to the surface of the substrate. In a specific embodiment, bias RF generator provides up to 5,000 watts of RF power at 13.56 MHz.

RF generators 31A and 31B include digitally controlled synthesizers and operate over a frequency range between about 1.8 to about 2.1 MHz. Each generator includes an RF control circuit (not shown) that measures reflected power from the chamber and coil back to the generator and adjusts the frequency of operation to obtain the lowest reflected power, as understood by a person of ordinary skill in the art. RF generators are typically designed to operate into a load with a characteristic impedance of 50 ohms. RF power may be reflected from loads that have a different characteristic impedance than the generator. This can reduce power transferred to the load. Additionally, power reflected from the load back to the generator may overload and damage the generator. Because the impedance of a plasma may range from less than 5 ohms to over 900 ohms, depending on the plasma ion density, among other factors, and because reflected power may be a function of frequency, adjusting the generator frequency according to the reflected power increases the power transferred from the RF generator to the plasma and protects the generator. Another way to reduce reflected power and improve efficiency is with a matching network.

Matching networks 32A and 32B match the output impedance of generators 31A and 31B with their respective coils 29 and 30. The RF control circuit may tune both matching networks by changing the value of capacitors within the matching networks to match the generator to the load as the load changes. The RF control circuit may tune a matching network when the power reflected from the load back to the generator exceeds a certain limit. One way to provide a constant match, and effectively disable the RF control circuit from tuning the matching network, is to set the reflected power limit above any expected value of reflected power. This may help stabilize a plasma under some conditions by holding the matching network constant at its most recent condition. Other measures may also help stabilize a plasma. For example, the RF control circuit can be used to determine the power delivered to the load (plasma) and may increase or decrease the generator output power to keep the delivered power substantially constant during a process.

A gas delivery system 33 provides gases from several sources, 34A-34F chamber for processing the substrate via gas delivery lines 38 (only some of which are shown). As would be understood by a person of skill in the art, the actual sources used for sources 34A-34F and the actual connection of delivery lines 38 to chamber 13 varies depending on the etching and cleaning processes executed within chamber 13. Gases are introduced into chamber 13 through a gas ring 37 and/or a top nozzle 45. FIG. 5B is a simplified, partial cross-sectional view of chamber 13 showing additional details of gas ring 37.

In one embodiment, first and second gas sources, 34A and 34B, and first and second gas flow controllers, 35A′ and 35B′, provide gas to ring plenum 36 in gas ring 37 via gas delivery lines 38 (only some of which are shown). Gas ring 37 has a plurality of source gas nozzles 39 (only one of which is shown for purposes of illustration) that provide a uniform flow of gas over the substrate. Nozzle length and nozzle angle may be changed to allow tailoring of the uniformity profile and gas utilization efficiency for a particular process within an individual chamber. In a preferred embodiment, gas ring 37 has 12 source gas nozzles made from an aluminum oxide ceramic.

Gas ring 37 also has a plurality of oxidizer gas nozzles 40 (only one of which is shown), which in a preferred embodiment are co-planar with and shorter than source gas nozzles 39, and in one embodiment receive gas from body plenum 41. In some embodiments it is desirable not to mix source gases and oxidizer gases before injecting the gases into chamber 13. In other embodiments, oxidizer gas and source gas may be mixed prior to injecting the gases into chamber 13 by providing apertures (not shown) between body plenum 41 and gas ring plenum 36. In one embodiment, third and fourth gas sources, 34C and 34D, and third and fourth gas flow controllers, 35C and 35D′, provide gas to body plenum via gas delivery lines 38. Additional valves, such as 43B (other valves not shown), may shut off gas from the flow controllers to the chamber.

In embodiments where flammable, toxic, or corrosive gases are used, it may be desirable to eliminate gas remaining in the gas delivery lines after a process. This may be accomplished using a 3-way valve, such as valve 43B, to isolate chamber 13 from delivery line 38A and to vent delivery line 38A to vacuum foreline 44, for example. As shown in FIG. 1A, other similar valves, such as 43A and 43C, may be incorporated on other gas delivery lines. Such 3-way valves may be placed as close to chamber 13 as practical, to minimize the volume of the unvented gas delivery line (between the 3-way valve and the chamber). Additionally, two-way (on-off) valves (not shown) may be placed between a mass flow controller (“MFC”) and the chamber or between a gas source and an MFC.

Referring again to FIG. 5A, chamber 13 also has top nozzle 45 and top vent 46. Top nozzle 45 and top vent 46 allow independent control of top and side flows of the gases, which improves gas flow uniformity and allows fine adjustment of the film's etching parameters. Top vent 46 is an annular opening around top nozzle 45. In one embodiment, first gas source 34A supplies source gas nozzles 39 and top nozzle 45. Source nozzle MFC 35A′ controls the amount of gas delivered to source gas nozzles 39 and top nozzle MFC 35A controls the amount of gas delivered to top gas nozzle 45. Similarly, two MFCs 35B and 35B′ may be used to control the flow of oxygen to both top vent 46 and oxidizer gas nozzles 40 from a single source of oxygen, such as source 34B. The gases supplied to top nozzle 45 and top vent 46 may be kept separate prior to flowing the gases into chamber 13, or the gases may be mixed in top plenum 48 before they flow into chamber 13. Separate sources of the same gas may be used to supply various portions of the chamber.

A remote microwave-generated plasma cleaning system 50 is provided to periodically clean residues from chamber components. The cleaning system includes a remote microwave generator 51 that creates a plasma from a cleaning gas source 34E (e.g., molecular fluorine, nitrogen trifluoride, other fluorocarbons or equivalents) in reactor cavity 53. The reactive species resulting from this plasma are conveyed to chamber 13 through cleaning gas feed port 54 via applicator tube 55. The materials used to contain the cleaning plasma (e.g., cavity 53 and applicator tube 55) must be resistant to attack by the plasma. The distance between reactor cavity 53 and feed port 54 should be kept as short as practical, since the concentration of desirable plasma species may decline with distance from reactor cavity 53. Generating the cleaning plasma in a remote cavity allows the use of an efficient microwave generator and does not subject chamber components to the temperature, radiation, or bombardment of the glow discharge that may be present in a plasma formed in situ. Consequently, relatively sensitive components, such as electrostatic chuck 20, do not need to be covered with a dummy substrate or otherwise protected, as may be required with an in situ plasma cleaning process. In one embodiment, this cleaning system is used to dissociate atoms of the etchant gas remotely, which are then supplied to the process chamber 13. In another embodiment, the etchant gas is provided directly to the process chamber 13. In still a further embodiment, multiple process chambers are used, with deposition and etching steps being performed in separate chambers.

System controller 60 controls the operation of system 10. In a preferred embodiment, controller 60 includes a memory 62, such as a hard disk drive, a floppy disk drive (not shown), and a card rack (not shown) coupled to a processor 61. The card rack may contain a single-board computer (SBC) (not shown), analog and digital input/output boards (not shown), interface boards (not shown), and stepper motor controller boards (not shown). The system controller conforms to the Versa Modular European (“VME”) standard, which defines board, card cage, and connector dimensions and types. The VME standard also defines the bus structure as having a 16 bit data bus and 24-bit address bus. System controller 31 operates under the control of a computer program stored on the hard disk drive or through other computer programs, such as programs stored on a removable disk. The computer program dictates, for example, the timing, mixture of gases, RF power levels and other parameters of a particular process. The interface between a user and the system controller is via a monitor, such as a cathode ray tube (“CRT”) 65, and a light pen 66, as depicted in FIG. 5C.

FIG. 5C is an illustration of a portion of an exemplary system user interface used in conjunction with the exemplary plasma processing chamber of FIG. 5A. System controller 60 includes a processor 61 coupled to a computer-readable memory 62. Preferably, memory 62 may be a hard disk drive, but memory 62 may be other kinds of memory, such as ROM, PROM, and others.

System controller 60 operates under the control of a computer program 63 stored in a computer-readable format within memory 62. The computer program dictates the timing, temperatures, gas flows, RF power levels and other parameters of a particular process. The interface between a user and the system controller is via a CRT monitor 65 and a light pen 66, as depicted in FIG. 5C. In a preferred embodiment, two monitors, 65 and 65A, and two light pens, 66 and 66A, are used, one mounted in the clean room wall (65) for the operators and the other behind the wall (65A) for the service technicians. Both monitors simultaneously display the same information, but only one light pen (e.g. 66) is enabled. To select a particular screen or function, the operator touches an area of the display screen and pushes a button (not shown) on the pen. The touched area confirms being selected by the light pen by changing its color or displaying a new menu, for example.

The computer program code can be written in any conventional computer-readable programming language such as 68000 assembly language, C, C++, or Pascal. Suitable program code is entered into a single file, or multiple files, using a conventional text editor and is stored or embodied in a computer-usable medium, such as a memory system of the computer. If the entered code text is in a high level language, the code is compiled, and the resultant compiler code is then linked with an object code of precompiled windows library routines. To execute the linked compiled object code, the system user invokes the object code causing the computer system to load the code in memory. The CPU reads the code from memory and executes the code to perform the tasks identified in the program.

FIG. 5D shows an illustrative block diagram of the hierarchical control structure of computer program 500. A user enters a process set number and process chamber number into a process selector subroutine 510 in response to menus or screens displayed on the CRT monitor by using the light pen interface. The process sets are predetermined sets of process parameters necessary to carry out specified processes, and are identified by predefined set numbers. Process selector subroutine 510 identifies (i) the desired process chamber in a multichamber system, and (ii) the desired set of process parameters needed to operate the process chamber for performing the desired process. The process parameters for performing a specific process relate to conditions such as process gas composition and flow rates, temperature, pressure, plasma conditions such as RF power levels, and chamber dome temperature, and are provided to the user in the form of a recipe. The parameters specified by the recipe are entered utilizing the light pen/CRT monitor interface.

The signals for monitoring the process are provided by the analog and digital input boards of system controller 60, and the signals for controlling the process are output on the analog and digital output boards of system controller 60.

A process sequencer subroutine 520 comprises program code for accepting the identified process chamber and set of process parameters from the process selector subroutine 510 and for controlling operation of the various process chambers. Multiple users can enter process set numbers and process chamber numbers, or a single user can enter multiple process set numbers and process chamber numbers; sequencer subroutine 520 schedules the selected processes in the desired sequence. Preferably, sequencer subroutine 520 includes a program code to perform the steps of (i) monitoring the operation of the process chambers to determine if the chambers are being used, (ii) determining what processes are being carried out in the chambers being used, and (iii) executing the desired process based on availability of a process chamber and type of process to be carried out. Conventional methods of monitoring the process chambers can be used, such as polling. When scheduling which process is to be executed, sequencer subroutine 520 can be designed to take into consideration the “age” of each particular user-entered request, or the present condition of the process chamber being used in comparison with the desired process conditions for a selected process, or any other relevant factor a system programmer desires to include for determining scheduling priorities.

After sequencer subroutine 520 determines which process chamber and process set combination is going to be executed next, sequencer subroutine 520 initiates execution of the process set by passing the particular process set parameters to a chamber manager subroutine 530A-C, which controls multiple processing tasks in chamber 13 and possibly other chambers (not shown) according to the process set sent by sequencer subroutine 520.

Examples of chamber component subroutines are substrate positioning subroutine 540, process gas control subroutine 550, pressure control subroutine 560, and plasma control subroutine 570. Those having ordinary skill in the art will recognize that other chamber control subroutines can be included depending on what processes are selected to be performed in chamber 13. In operation, chamber manager subroutine 530A selectively schedules or calls the process component subroutines in accordance with the particular process set being executed. Chamber manager subroutine 530A schedules process component subroutines in the same manner that sequencer subroutine 520 schedules the process chamber and process set to execute. Typically, chamber manager subroutine 530A includes steps of monitoring the various chamber components, determining which components need to be operated based on the process parameters for the process set to be executed, and causing execution of a chamber component subroutine responsive to the monitoring and determining steps.

Operation of particular chamber component subroutines will now be described with reference to FIGS. 5A and 5D. Substrate positioning subroutine 540 comprises program code for controlling chamber components that are used to load a substrate onto substrate support number 18. Substrate positioning subroutine 540 may also control transfer of a substrate into chamber 13 from, e.g., another reactor in the multi-chamber system, after other processing has been completed.

Process gas control subroutine 550 has program code for controlling process gas composition and flow rates. Subroutine 550 controls the open/close position of the safety shut-off valves and also ramps up/ramps down the mass flow controllers to obtain the desired gas flow rates. All chamber component subroutines, including process gas control subroutine 550, are invoked by chamber manager subroutine 530A. Subroutine 550 receives process parameters from chamber manager subroutine 530A related to the desired gas flow rates.

Typically, process gas control subroutine 550 opens the gas supply lines, and repeatedly (i) reads the necessary mass flow controllers, (ii) compares the readings to the desired flow rates received from chamber manager subroutine 530A, and (iii) adjusts the flow rates of the gas supply lines as necessary. Furthermore, process gas control subroutine 550 may include steps for monitoring the gas flow rates for unsafe rates and for activating the safety shut-off valves when an unsafe condition is detected.

In some processes, an inert gas, such as argon, is flowed into chamber 13 to stabilize the pressure in the chamber before reactive process gases are introduced. For these processes, the process gas control subroutine 550 is programmed to include steps for flowing the inert gas into chamber 13 for an amount of time necessary to stabilize the pressure in the chamber. The steps described above may then be carried out.

Additionally, when a process gas is to be vaporized from a liquid precursor, for example, tetraethylorthosilane (TEOS), the process gas control subroutine 550 may include steps for bubbling a delivery gas such as helium through the liquid precursor in a bubbler assembly or for introducing the helium to a liquid injection valve. For this type of process, the process gas control subroutine 550 regulates the flow of the delivery gas, the pressure in the bubbler, and the bubbler temperature to obtain the desired process gas flow rates. As discussed above, the desired process gas flow rates are transferred to process gas control subroutine 550 as process parameters.

Furthermore, the process gas control subroutine 550 includes steps for obtaining the necessary delivery gas flow rate, bubbler pressure, and bubbler temperature for the desired process gas flow rate by accessing a stored table containing the necessary values for a given process gas flow rate. Once the necessary values are obtained, the delivery gas flow rate, bubbler pressure and bubbler temperature are monitored, compared to the necessary values and adjusted accordingly.

The process gas control subroutine 550 may also control the flow of heat-transfer gas, such as helium (He), through the inner and outer passages in the substrate chuck with an independent helium control (IHC) subroutine (not shown). The gas flow thermally couples the substrate to the chuck. In a typical process, the substrate is heated by the plasma and the chemical reactions that etch the layer, and the He cools the substrate through the chuck, which may be water-cooled. This keeps the substrate below a temperature that may damage preexisting features on the substrate.

Pressure control subroutine 560 includes program code for controlling the pressure in chamber 13 by regulating the size of the opening of throttle valve 26 in the exhaust portion of the chamber. There are at least two basic methods of controlling the chamber with the throttle valve. The first method relies on characterizing the chamber pressure as it relates to, among other things, the total process gas flow, the size of the process chamber, and the pumping capacity. The first method sets throttle valve 26 to a fixed position. Setting throttle valve 26 to a fixed position may eventually result in a steady-state pressure.

Alternatively, the chamber pressure may be measured, with a manometer for example, and the position of throttle valve 26 may be adjusted according to pressure control subroutine 560, assuming the control point is within the boundaries set by gas flows and exhaust capacity. The former method may result in quicker chamber pressure changes, as the measurements, comparisons, and calculations associated with the latter method are not invoked. The former method may be desirable where precise control of the chamber pressure is not required, whereas the latter method may be desirable where an accurate, repeatable, and stable pressure is desired.

When pressure control subroutine 560 is invoked, the desired, or target, pressure level is received as a parameter from chamber manager subroutine 530A. Pressure control subroutine 560 measures the pressure in chamber 13 by reading one or more conventional pressure manometers connected to the chamber; compares the measured value(s) to the target pressure; obtains proportional, integral, and differential (PID) values from a stored pressure table corresponding to the target pressure, and adjusts throttle valve 26 according to the PID values obtained from the pressure table. Alternatively, pressure control subroutine 160 may open or close throttle valve 26 to a particular opening size to regulate the pressure in chamber 13 to a desired pressure or pressure range.

Plasma control subroutine 570 comprises program code for controlling the frequency and power output setting of RF generators 31A and 31B and for tuning matching networks 32A and 32B. Plasma control subroutine 570, like the previously described chamber component subroutines, is invoked by chamber manager subroutine 530A.

An example of a system that may incorporate some or all of the subsystems and routines described above would be the ULTIMA™ system, manufactured by APPLIED MATERIALS, INC., of Santa Clara, Calif., configured to practice the present invention. Further details of such a system are disclosed in the commonly assigned U.S. patent application Ser. No. 08/679,927, filed Jul. 15, 1996, entitled “Symmetric Tunable Inductively-Coupled HDP-CVD Reactor,” having Fred C. Redeker, Farhad Moghadam, Hirogi Hanawa, Tetsuya Ishikawa, Dan Maydan, Shijian Li, Brian Lue, Robert Steger, Yaxin Wang, Manus Wong and Ashok Sinha listed as co-inventors, the disclosure of which is incorporated herein by reference. The described system is for exemplary purpose only. It would be a matter of routine skill for a person of skill in the art to select an appropriate conventional substrate processing system and computer control system to implement the present invention.

While a detailed description of presently preferred embodiments of the invention have been given above, various alternatives, modifications, and equivalents will be apparent to those skilled in the art without varying from the spirit of the invention. Therefore, the above description should not be taken as limiting the scope of the invention, which is defined by the appended claims.

What is claimed is:

1. A method for etching a substrate, the method comprising:
disposing the substrate in a process chamber;
providing a flow of precursor gas into the process chamber;
forming an ionic plasma from the precursor gas in a plasma volume within the process chamber;
generating a magnetic field in said process chamber using magnetic sources disposed external to said plasma volume, wherein said magnetic field divides said ionic plasma into a first region and a second region, the second region confined substantially above the substrate, plasma within the first region having a higher electron temperature than plasma within the second region; and
forming radicals from plasma within the second region above said substrate for etching said substrate.

2. The method recited in claim 1 wherein the ionic plasma is a negative-ion plasma.

3. The method recited in claim 1 wherein the substrate comprises a silicon oxide layer.

4. The method recited in claim 1 wherein forming the ionic plasma from the precursor gas comprises ionizing the precursor gas using a radio-frequency source.

5. The method recited in claim 4 wherein the precursor gas comprises freon molecules.

6. The method recited in claim 5 wherein the precursor gas further comprises argon.

7. The method recited in claim 5 wherein the precursor gas comprises C₄F₈ molecules and forming radicals from plasma within the second region comprises dissociating the C₄F₈ molecules into radical species including CF₂.

8. The method recited in claim 5 wherein the precursor gas comprises C₄F₈ molecules and forming radicals from plasma within the second region comprises dissociating the C₄F₈ molecules into radical species including CF₃.

9. The method recited in claim 1 wherein the magnetic sources comprise permanent magnets.

10. The method recited in claim 1 wherein the magnetic sources comprise electromagnets.

11. The method recited in claim 1 wherein the radicals are neutral radicals.

12. A substrate processing system comprising:
a housing defining a process chamber;
an ionic-plasma generating system operatively coupled to the process chamber;
a substrate holder configured to hold a substrate during substrate processing;
a gas-delivery system configured to introduce gas into the process chamber;
a pressure-control system for maintaining a selected pressure within the process chamber;
a controller for controlling the ionic-plasma generating system, the gas-delivery system, and the pressure-control system to form an ionic plasma within the process chamber; and
a magnetic source disposed outside the process chamber for generating a magnetic field, wherein the magnetic field divides the ionic plasma into a first region and a second region, plasma within the first region having a higher electron temperature than plasma within the second region such that plasma within the second region is confined substantially above the substrate to form radicals for etching the substrate.

13. The substrate processing system recited in claim 12 wherein the ionic plasma is a negative-ion plasma.

14. The substrate processing system recited in claim 12 wherein the gas comprises freon molecules.

15. The substrate processing system recited in claim 14 wherein the gas further comprises argon.

16. The substrate processing system recited in claim 14 wherein the freon molecules comprise C₄F₈ molecules and the radicals comprise CF₂ radicals.

17. The substrate processing system recited in claim 14 wherein the freon molecules comprise C₄F₈ molecules and the radicals comprise CF₃ radicals.

18. The substrate processing system recited in claim 12 wherein the ionic-plasma generating system comprises radio-frequency coils.

19. The substrate processing system recited in claim 12 wherein the magnetic source comprises a permanent magnet.

20. The substrate processing system recited in claim 12 wherein the magnetic source comprises an electromagnet.

21. The substrate processing system recited in claim 12 wherein the substrate comprises a dielectric material.

22. The substrate processing system recited in claim 21 wherein the dielectric material comprises silicon oxide.

23. The substrate processing system recited in claim 12 wherein electrons in the plasma within the second region have an energy between approximately 1 and 300 eV.
